(19) United States
(12) Patent Application Publication
(10) Pub. No.: US 2018/0166369 A1
(43) Pub. Date: Jun. 14, 2018

(54) Bi-Layer Nanoparticle Adhesion Film

(71) Applicant: TEXAS INSTRUMENTS INCORPORATED, Dallas, TX (US)

(72) Inventors: Benjamin Stassen Cook, Addison, TX (US); Yong Lin, Plano, TX (US)

(21) Appl. No.: 15/378,236

(22) Filed: Dec. 14, 2016

(51) Int. Cl. H01L 23/495; H01L 23/00; H01L 21/48; H01L 23/29; B32B 15/092; B32B 7/10

(52) U.S. Cl. CPC H01L 23/49586; B32B 2457/14; H01L 24/32; H01L 21/4821; H01L 23/293; B32B 15/092; B32B 7/10; H01L 2224/32245; B32B 2250/02; B32B 2255/06; B32B 2255/28; B32B 2255/205; B32B 2307/7246; B32B 2307/71; H01L 23/49582

(57) ABSTRACT

A device comprises a substrate) of a first material with a surface, which is modified by depositing a bi-layer nanoparticle film. The film includes a nanoparticle layer of a second material on top of and in contact with surface, and a nanoparticle layer of a third material on top of and in contact with the nanoparticle layer of the second material. The nanoparticles of the third material adhere to the nanoparticles of the second material. The substrate region adjoining surface comprises an admixture of the second material in the first material. A fourth material contacts and chemically/mechanically bonds to the nanoparticle layer of the third material.

### FIELD

Embodiments of the present invention are related in general to the field of semiconductor devices and processes, and more specifically to the structure and fabrication of bi-layer nanoparticle adhesion films applied to packaged semiconductor devices for improving adhesion of the interface between different materials.

### DESCRIPTION OF RELATED ART

Based on their functions, semiconductor packages include a variety of different materials. Metals formed as leadframes and bonds are employed for mechanical stability, and electrical and thermal conductance. Insulators, such as polymeric molding compounds, are used for encapsulations and form factors. During packaging fabrication, it is common practice to attach a plurality of semiconductor chips to a strip of a leadframe, to connect the chips to their respective leads, and then to encapsulate the assembled chips in packages. Packages protect enclosed parts against mechanical damage and environmental influences such as moisture and light.

A popular encapsulation technique is a transfer molding method. A leadframe strip with attached and connected chips is placed in a steel mold, which forms a cavity around each assembled chip. A semi-viscous thermoset polymeric compound is pressured through runners across the leadframe strip to enter each cavity through a gate. After filling the cavities, the compound is allowed to harden by polymerization. Finally, in the degating step, the compound in the runner is broken off at each gate from the compound filling the cavity.

To ensure the unity and coherence of the package, the metallic and non-metallic materials are expected to adhere to each other during the lifetime of the product. Failing adhesion allows moisture ingress into the package, causing device failure by electrical leakage and chemical corrosion. It may further lead to failure of the attachment of semiconductor chips to substrates, to breakage of wire bonds, cracking of solder bumps, and to degraded thermal and electrical energy dissipation.

Today's semiconductor technology employs a number of methods to improve adhesion between the diversified materials so that the package passes accelerated test and use conditions without delamination. Among the methods are chemically purifying the molding compound, activating leadframe metal surfaces for instance by plasma just prior to the molding process, and enhancing the affinity of leadframe metals to polymeric compounds by oxidizing the base metal. Furthermore, design features such as indentations, grooves or protrusions, overhangs and other three-dimensional features are added to the leadframe surface for improved interlocking with the package material.

Another example of known technology to increase adhesion between leadframe, chip, and encapsulation compound in semiconductor packages, is the roughening of the whole leadframe surface by chemically etching the leadframe surface after stamping or etching the pattern from a metal sheet. Chemical etching is a subtractive process using an etchant. Chemical etching creates a micro-crystalline metal surface with a roughness on the order of 1 μm or less. To roughen only one surface of the leadframe adds about 10 to 15% cost to the non-roughened leadframe.

Yet another known method to achieve a rough surface is the use of a specialized metal plating bath, such as a nickel plating bath, to deposit a rough metal (such as nickel) layer. This method is an additive process. The created surface roughness is on the order of 1 to 10 μm. Roughening of the leadframe surface may have some unwelcome side effects. General roughening of the surface impacts wire bonding negatively, since vision systems have trouble seeing the roughened surface; the rough surface shortens capillary life; and micro-contaminants on the rough surface degrades bonding consistency. Generally, rough surfaces tend to allow more bleeding, when the resin component separates from the bulk of the chip attach compound and spreads over the surface of the chip pad. The resin bleed, in turn, can degrade moisture level sensitivity and interfere with down bonds on the chip pad. Selective roughening technique is sometimes employed, which involves reusable silicone rubber masks or gaskets; consequently, selective roughening is expensive. For example, protective masks to restrict the chemical roughening to the selected leadframe areas add about 35 to 40% cost to the non-roughened leadframe.

The success of all these efforts has been limited, especially because the adhesive effectiveness is diminishing ever more when another downscaling step of device miniaturization is implemented.

### SUMMARY

An embodiment of the invention includes a substrate (201) of a first material with a surface (201a). The surface (201a) is modified by depositing a bi-layer nanoparticle film. The bi-layer nanoparticle film includes a nanoparticle layer (400) of a second material an top of and in contact with the surface (201a), and a nanoparticle layer (500) of a third material on top of and in contact with the nanoparticle layer (400) of the second material. The nanoparticles of the third material adhere to the nanoparticles of the second material. A substrate region adjoining surface (201a) comprises an admixture of the second material in the first material. A fourth material has a surface in contact with and chemically/mechanically bonded to the nanoparticle layer (500) of the third material.

### BRIEF DESCRIPTION OF THE DRAWINGS

FIG. 1 is a diagram summarizing the process flow of creating an additive bi-layer nanoparticle adhesion film for enhancing adhesion between objects of dissimilar material according to an embodiment of the invention.

FIG. 2 illustrates an embodiment of the invention comprising the formation of an additive layer of nanoparticles of a second material on the surface of a substrate of a first material.

FIG. 3 shows an enlargement of a portion of a syringe with a nozzle in FIG. 2, wherein the syringe is filled with a paste of nanoparticles of a second material in a solvent according to an embodiment of the invention.

FIG. 4 depicts the additive layer after sintering the nanoparticles of the second material, concurrently with diffusing second material into the substrate region adjoining the substrate surface according to an embodiment of the invention.

FIG. 5 illustrates the formation of an additive layer of nanoparticles of a third material on the surface of a layer of sintered nanoparticles of to second material according to an embodiment of the invention.

FIG. 6 shows an enlargement of a portion of the syringe with a nozzle in FIG. 5, wherein the syringe is filled with a paste of nanoparticles of a third material in a solvent according to an embodiment of the invention.

FIG. 7 shows the encapsulation of an additive bi-layer nanoparticle adhesion film by a packaging compound, which fills any voids of an additive layer of the third material according to an embodiment of the invention.

FIG. 8 illustrates another embodiment of the invention comprising the formation of an additive layer of nanoparticles using a solvent including a mixture of nanoparticles of a second material and nanoparticles of a third material.

FIG. 9 shows an enlargement of a portion of the syringe with a nozzle in FIG. 8, wherein the syringe is filled with a paste including a mixture of nanoparticles of a second material and nanoparticles of a third material in a solvent according to an embodiment of the invention.

FIG. 10 depicts an exemplary packaged semiconductor device having portions of its leadframe covered with a bi-layer nanoparticle adhesion film, enhancing the adhesion between the leadframe and the plastic package according to an embodiment of the invention.

FIG. 11 illustrates a nanoparticle core with different hydrophobic ligand molecules, both drawn to scale (Prior Art).

### DETAILED DESCRIPTION OF THE PREFERRED EMBODIMENTS

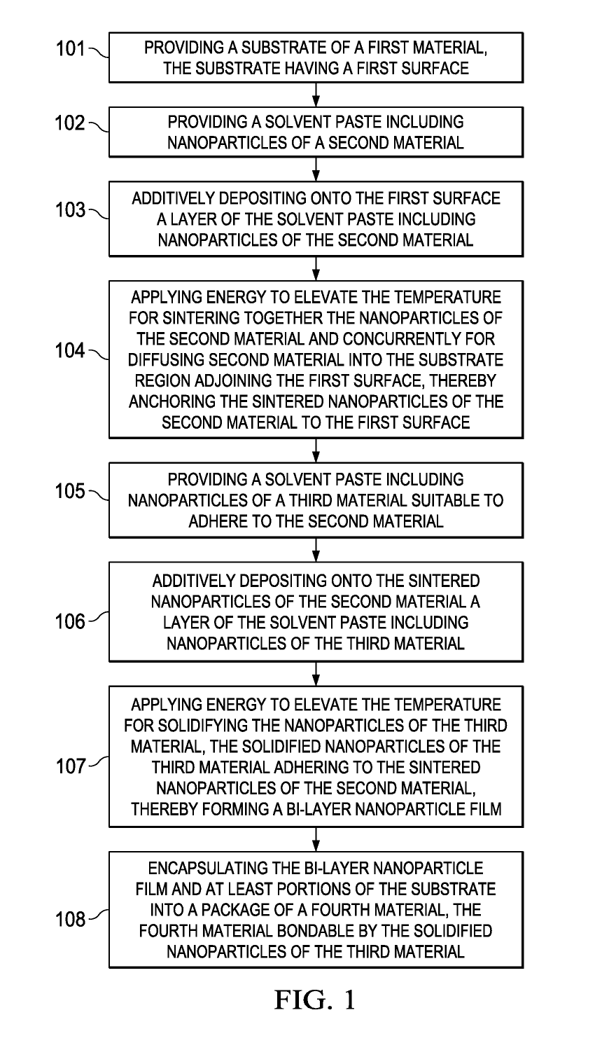

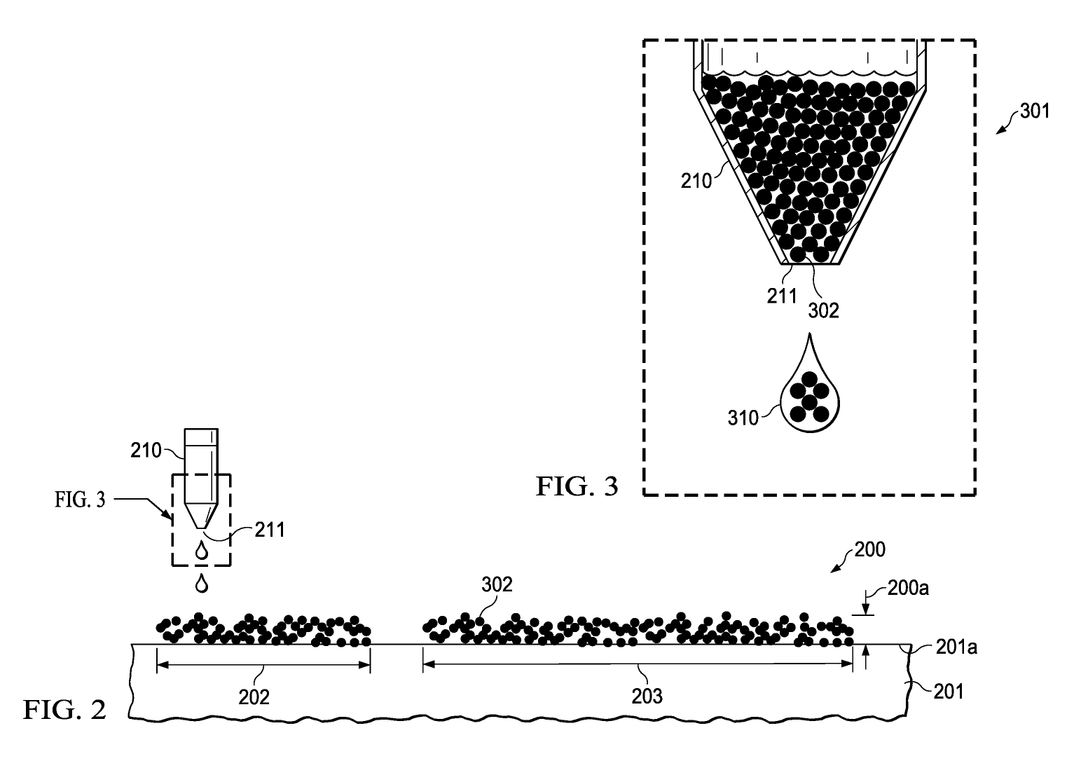

In an embodiment of the invention, a method for enhancing the adhesion and mechanical bonding between diverse materials is described. The method comprises the formation and anchoring of an additive adhesion film composed of two superimposed (or alternatively, intermeshed) nanoparticle layers between the materials. FIG. 1 is a diagram summarizing an embodiment of the invention. A material, onto which an additive film is constructed, is herein referred to as substrate, while another material, which needs adhesion to the substrate, is herein referred to as package. As examples, a substrate is denoted 201 in FIG. 2, and a package is denoted 701 in FIG. 7.

An application of the process flow shown in FIG. 1 can be applied to the fabrication technology of semiconductor devices. In semiconductor technology, the substrate typically is either a metallic leadframe or a laminated substrate composed of a plurality of alternating electrically insulating and electrically conductive layers. In process 101 of FIG. 1, a substrate is selected, which is made of a first material and has a surface extending in two dimensions.

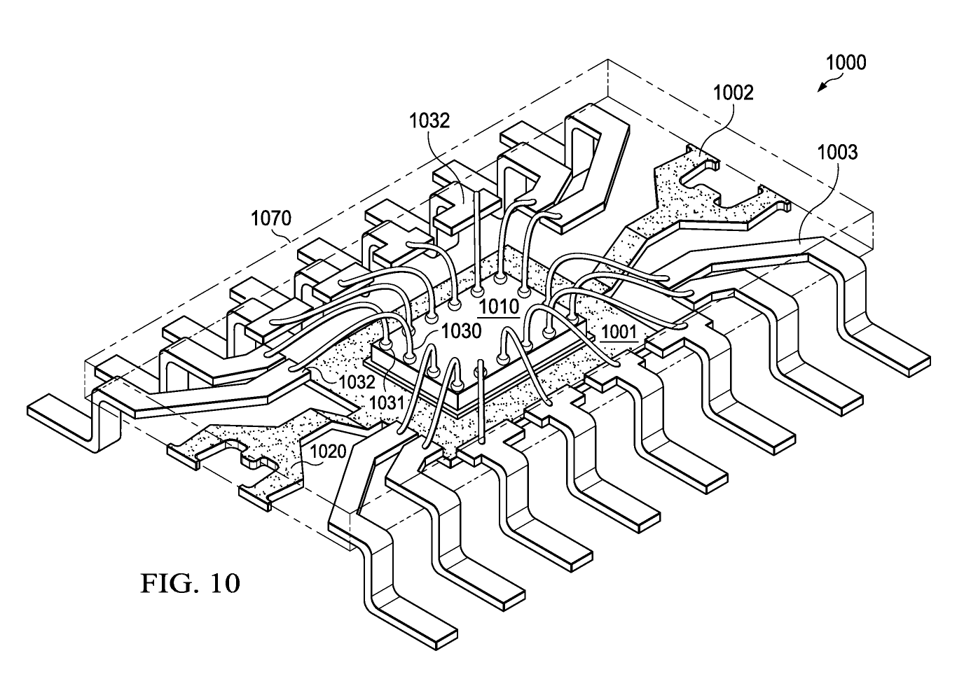

When the substrate is a leadframe (see FIG. 10), such leadframe is preferably etched or stamped from a thin sheet of base metal such as copper, copper alloy, iron-nickel alloy, aluminum, Kovar™, and others, in a typical thickness range from 120 to 250 μm. As used herein, the term base metal has the connotation of starting material and does not imply a chemical characteristic. Some leadframes may have additional metal layers plated onto the complete or the partial surface areas of the base metal; examples are plated nickel, palladium, and gold layers on copper leadframes.

A leadframe provides a stable support pad (1001 in FIG. 10) for firmly positioning the semiconductor chip (1010). Further, a leadframe offers a multitude of conductive leads (1003) to bring various electrical conductors into close proximity of the chip. Any remaining gap between the tip of the leads and the chip terminals is typically bridged by bonding wires (1030). Alternatively, in flip-chip technology the chip terminals may be connected to the leads by metal bumps.

It is important that leadframe characteristics facilitate reliable adhesion to an attached chip and to packaging compounds (1070 in FIG. 10). Besides chemical affinity between the molding compound and the metal finish of the leadframe, adhesion may necessitate leadframe surface roughness, especially in view of the technical trend of shrinking package dimensions, which offers less surface area for adhesion. In addition, the requirement to use lead-free solders pushes the reflow temperature range into the neighborhood of about 260° C., making it more difficult to maintain mold compound adhesion to the leadframes at elevated temperatures.

Referring to the process flow of FIG. 1, during step 102 of the process flow a solvent paste is provided, which comprises a dispersant or solvent including nanoparticles of a second material. An example of a solvent paste is illustrated in FIG. 3 and designated 301. The nanoparticles, dissolved in the dispersant, are referred to as nanoparticles 302 of a second material. The concept of nanoparticles as used herein includes spherical or other three-dimensional clusters composed of atoms or molecules, of inorganic or organic chemical compounds, of one-dimensional wires, of two-dimensional crystals and platelets, and of nanotubes.

Nanoparticles 302 may be selected from a group including metals, metal oxides, oxides, and ceramics. The metals may include gold, silver, copper, aluminum, tin, zinc, and bismuth. Metal oxides may include copper oxide, which, as a mixture of cupric and cuprous oxide with a varying ratio, is known to offer better chemical adhesion to molding compounds than copper.

During step 103 of the process flow of FIG. 1, a layer 200 of the solvent paste 301, which includes nanoparticles of the second material, is additively deposited on a surface 201a of the substrate 201 shown in FIG. 2. Layer 200 may extend over the available two-dimensional surface area, or it may cover only portions of the surface area such as islands between about 0.1 μm to 100 μm dependent on the drop size of the solvent paste.

The equipment for depositing the solvent paste includes a computer-controlled inkjet printer with a moving syringe 210 with nozzle 211, from which discrete drops 310 of the paste are released. Automated inkjet printers can be selected from a number of commercially available printers. Alternatively, a customized inkjet printer can be designed to work for specific pastes. Alternatively, any additive method can be used including inkjet printing, screen printing, gravure printing, dip coating, spray coating, and many others.

As stated, the deposited layer 200 may extend along the lateral dimensions of the substrate 201, or may include, as depicted in FIG. 2 as exemplary lengths 202 and 203, islands extending for about 0.1 μm to 100 μm length. In metallic leadframes, layer 200 may cover the whole leadframe surface area of one or more leads, or selected parts such as the chip attach pad. Building up height from compiled drops of repeated runs of syringe 210, layer 200 may have a height 200a between about 100 nm and 500 nm, but may be thinner or considerably thicker.

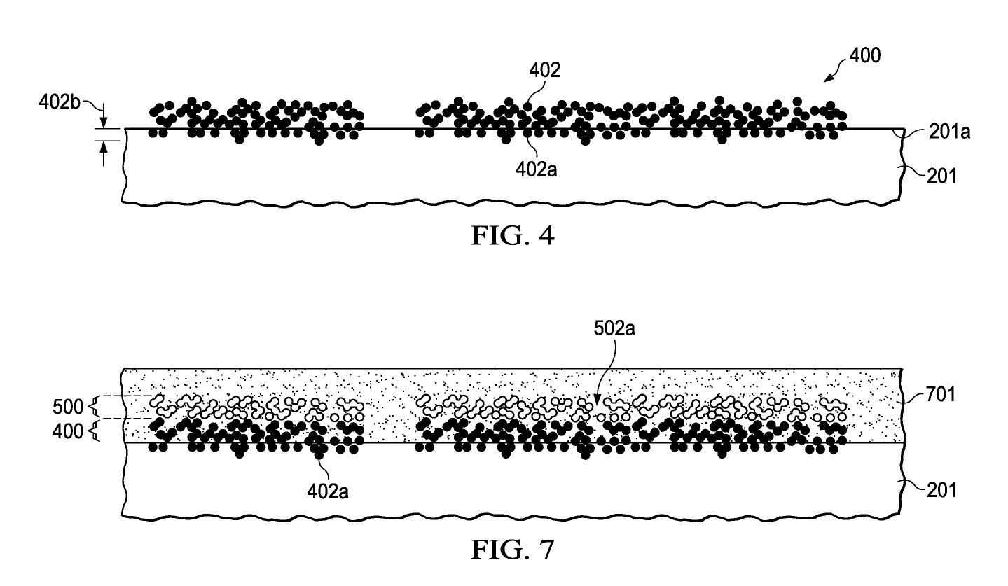

During step 104 of the process flow of FIG. 1, energy is provided to elevate the temperature for sintering together the nanoparticles of the second material and concurrently for diffusing the second material into the substrate region adjoining the first surface, thereby anchoring the sintered nanoparticles of the second material to the first surface. The needed energy may be provided by a plurality of sources: thermal energy, photonic energy, electromagnetic energy, and chemical energy. When sintering together, the nanoparticles 302 are necking between the particles into a liquid network structure 402. The liquid network structure 402 is forming layer 400 in FIG. 4.

Concurrent with the sintering of the nanoparticles 402 of the second material, some second material is diffusing by atomic interdiffusion into the first material of the region adjoining the surface 201a (first surface) of substrate 201. In FIG. 4, the second material interdiffused into the region near surface 201a of substrate 201 is designated 402a. The diffusion depth is designated 402b in FIG. 4. The atomic interdiffusion into the substrate creates an interdiffusion bond, which anchors layer 400 of sintered second nanoparticles into substrate 201.

After the sintering process, the liquid network structure 402 of second material is solidified to create a solid layer 400 of second material 402. Since the hardened network structure 400 remains at the substrate surface as a solid layer, the nanoparticles 402 of the second material are structural nanoparticles.

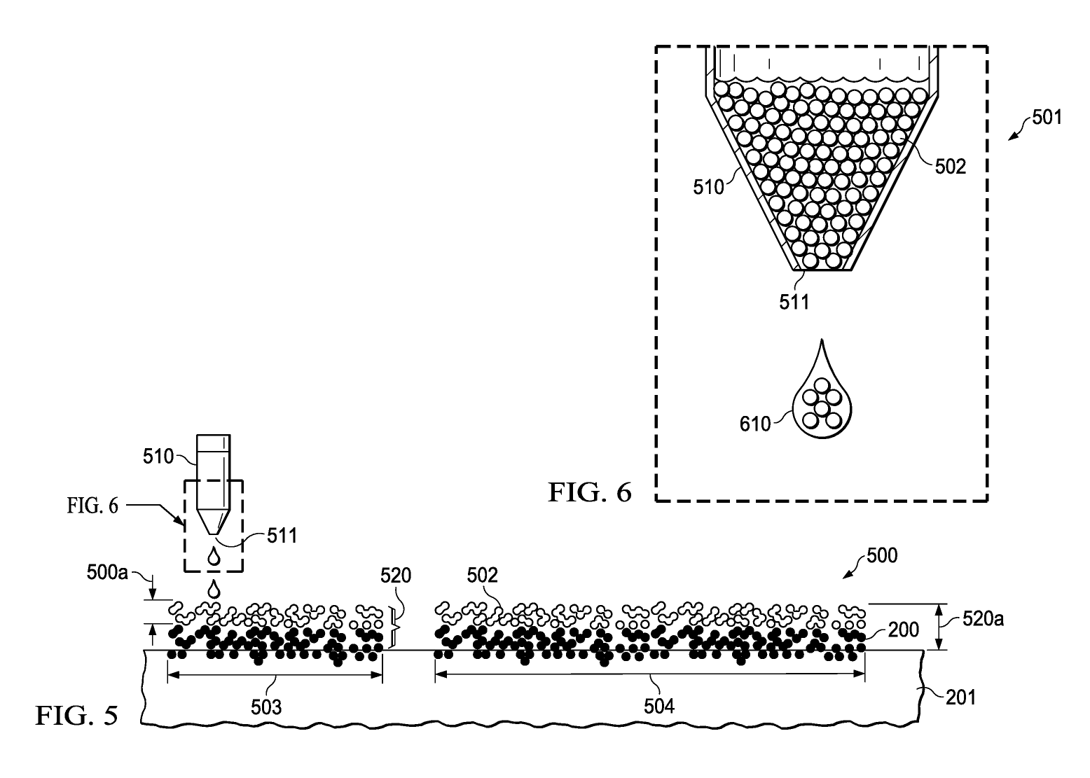

During the process step 105 of the process flow shown in FIG. 1, another solvent paste is provided, which comprises a dispersant or solvent including nanoparticles of a third material. An example of a solvent paste is illustrated in FIG. 5 and designated 501. The nanoparticles, dissolved in the dispersant, are referred to as nanoparticles 502 of a third material. The third material may be selected from a group including polymers, oxides, ceramics, metals, and metal oxides. The metals may include gold, silver, copper, aluminum, tin, zinc, and bismuth, and the metal oxides may include copper oxide, which, as a mixture of cupric and cuprous oxide with a varying ratio, is known to offer better chemical adhesion to molding compounds than copper.

In conjunction with the selection of the nanoparticles of the second material, the nanoparticles of the third material are selected so that they are operable to have adhesion to the nanoparticles of the second material. Due to intermolecular forces, the nanoparticles of the third material cling to the nanoparticles of the second material. In a related effect, an increase of surface tension, or surface energy, causes an increase of adhesion and wetting to a surface.

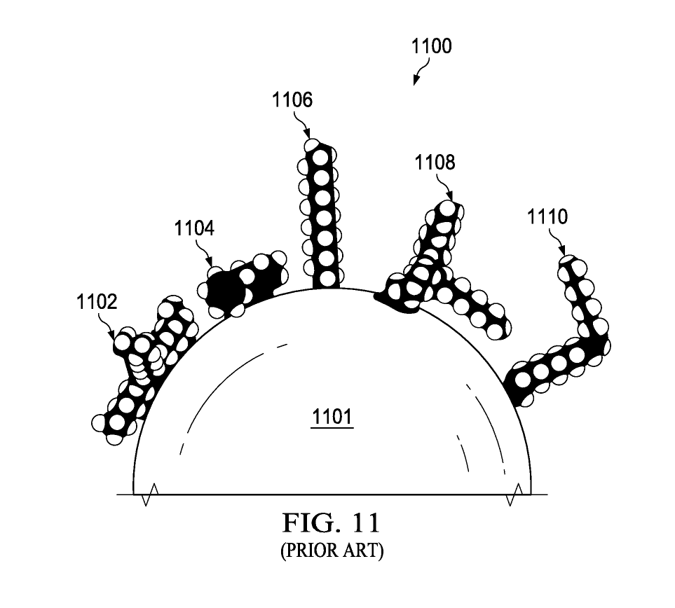

When surfaces of nanoparticles are treated so that the treated nanoparticles are enabled to perform certain desired functions, such treatment is referred to as functionalization. For example, if nanoparticles are desired to stay separate from each other, they can be treated with ligands (they are “functionalized”) to prevent coagulation. In the example described in FIG. 2, it is advantageous to functionalize the surfaces of the nanoparticles of the third material for improved adhesion to the nanoparticles of the second material. FIG. 11 illustrates a nanoparticle 1100 with a core 1101 idealized as a smooth sphere of 5 nm diameter together with different hydrophobic ligand molecules drawn to scale and attached to the surface of core 1101. The ligand molecules in FIG. 11 include molecule 1102 (trioctylphosphine oxide, TOPO), molecule 1104 (triphenylphosphine, TPP), molecule 1106 (dodecanethiol, DDT), molecule 1108 (tetraoctylammonium bromide, TOAB), and molecule 1110 (oleic acid, OA).

The cores of other nanoparticles may have hydrophilic ligand molecules attached to the core surface. Examples include mercaptoacetic acid (MAA), mercaptopropionic acid (MPA), mercaptoundecanoic acid (MUA), mercaptosuccinic acid (MSA), dihydrolipic acid (DHLA), bis-sulphonated triphenylphosphine (mPEG₅-SH, mPEG₄₅-SH), and short peptide of sequence CALNN. Ligand molecules such as inert molecular chains attached on the surface of the core can stabilize the nanoparticles against aggregation, while other ligand molecules attached on the surface can enhance the adhesion to objects.

As an example, for promoting covalent bonding of copper oxide (both CuO and Cu₂O) nanoparticles, molecules of siloxane, silane, or the amine-group may be attached to the core surface to functionalize copper oxide nanoparticles.

For some applications, adhesion between the layer of the third material and the layer of the second material can be achieved, when the third material is the same chemical element as the second material but has different porosity or a different compound formulation leading to a different surface function. As an example, the third material may be a compound of the amine group or the silane group of the same element as the second material or the third material may belong to a different oxide formulation, for example CuO vs. Cu₂O. As another example, the material density may be different, or the size or density of the porosity (regular vs. random configuration). As yet another example, the third material may have a different diffusion characteristic into solids along grain boundaries or lattice defects.

During step 106 of the process flow shown in FIG. 1, a layer 500 of the solvent paste 501, which includes nanoparticles of the third material, is additively deposited on layer 200 of sintered nanoparticles of the second material. The process is illustrated in FIG. 5; the thickness of layer 500 of nanoparticles of the third material is 500a. Layer 500 may extend over the available two-dimensional surface area of substrate 201, or, as depicted in FIG. 5 as exemplary lengths 503 and 504, it may cover only portions of the surface area such as islands between about 0.1 μm to 100 μm dependent on the drop size of the solvent paste.

The equipment for the deposition includes a computer-controlled inkjet printer with a moving syringe 510 with nozzle 511, from which discrete drops 610 of the paste are discontinuously released. Automated inkjet printers can be selected from a number of commercially available printers. Alternatively, a customized inkjet printer can be designed to work for specific pastes. Alternatively, any additive method can be used including screen printing, gravure printing, flexographic printing, dip coating, spray coating, and inkjet printing comprising piezoelectric, thermal, acoustic and electrostatic inkjet printing.

As stated, the deposited layer 500 may extend along the lateral dimensions of the whole substrate 201, or may, as depicted in FIG. 5, include islands extending for about 0.1 μm to 100 μm length. In metallic leadframes, layer 500 may cover the whole leadframe surface area of only one or more leads, or selected parts such as the chip attach pad. Building up height from compiled drops of repeated runs of syringe 510, layer 500 may preferably have a height 500a between about 100 nm and 500 nm, but may be thinner or considerably thicker.

During step 107 of the process flow shown in FIG. 1, energy is provided to increase the temperature for sintering together the nanoparticles of the third material. The needed energy may be provided by a plurality of sources: thermal energy, photonic energy, electromagnetic energy, and chemical energy. When sintering together, the nanoparticles 502 are necking between the particles into a liquid network structure. In the necking connections, the surfaces of the molten particles exhibit a constricted range resembling a neck between the particles. The liquid network structure is forming layer 500 in FIG. 4. After the sintering process, the liquid network structure of third material is solidified to create a solid layer 400 of third material.

With the nanoparticles of the third material sintered, solidified, and adhering to the sintered nanoparticles of the second material, a bi-layer nanoparticle film 520 is formed. The thickness 520a of bi-layer film 520 is preferably between about 0.1 μm and 10 μm.

During step 108 of the process flow shown in FIG. 1, the solid bi-layer nanoparticle film 520, together with at least portions of the substrate 201 of first material, are encapsulated into a package of polymeric compound. The process is illustrated in FIG. 7, wherein the polymeric compound is denoted 701. A method for encapsulation by a polymeric compound is transfer molding technology using a thermoset epoxy-based molding compound. Since the compound has low viscosity at the elevated temperature during the molding process, the polymeric compound can readily fill any pores/voids 502a in the layer 500 of third material. The filling of the pores/voids by polymeric material takes place for any pores/voids, whether they are arrayed in an orderly pattern or in a random distribution, and whether they are shallow or in a random three-dimensional configuration including pores/voids resembling spherical caverns with narrow entrances.

After the compound has polymerized and cooled down to ambient temperature, the polymeric compound 701 in the package as well as in the pores/voids is hardened. After hardening of the plastic material, the polymeric-filled pores/voids represent an anchor of the package in the nanoparticle layer 500, giving strength to the interface of package (fourth material) and the bi-layer nanoparticle film (third material). In addition, as mentioned above, layer 500 has adhesion to nanoparticle layer 400, giving the bi-layer film strength. In turn, layer 400 is anchored in metallic substrate 201 by metal interdiffusion 402a, giving the interface of the bi-layer film to the substrate strength. As an overall result, the bi-layer nanoparticle film improves the adhesion between the plastic package 701 and the metallic substrate 201. Adhesion improvements of an order of magnitude have been measured.

In addition to mechanical adhesion between bodies, the overall adhesion between two different materials can be improved by chemical adhesion. Consequently, the nanoparticles of the second material and third material can be chosen to enhance chemical adhesion. As an example, copper oxide nanoparticles have better chemical bonding to polymeric molding compounds than gold nanoparticles.

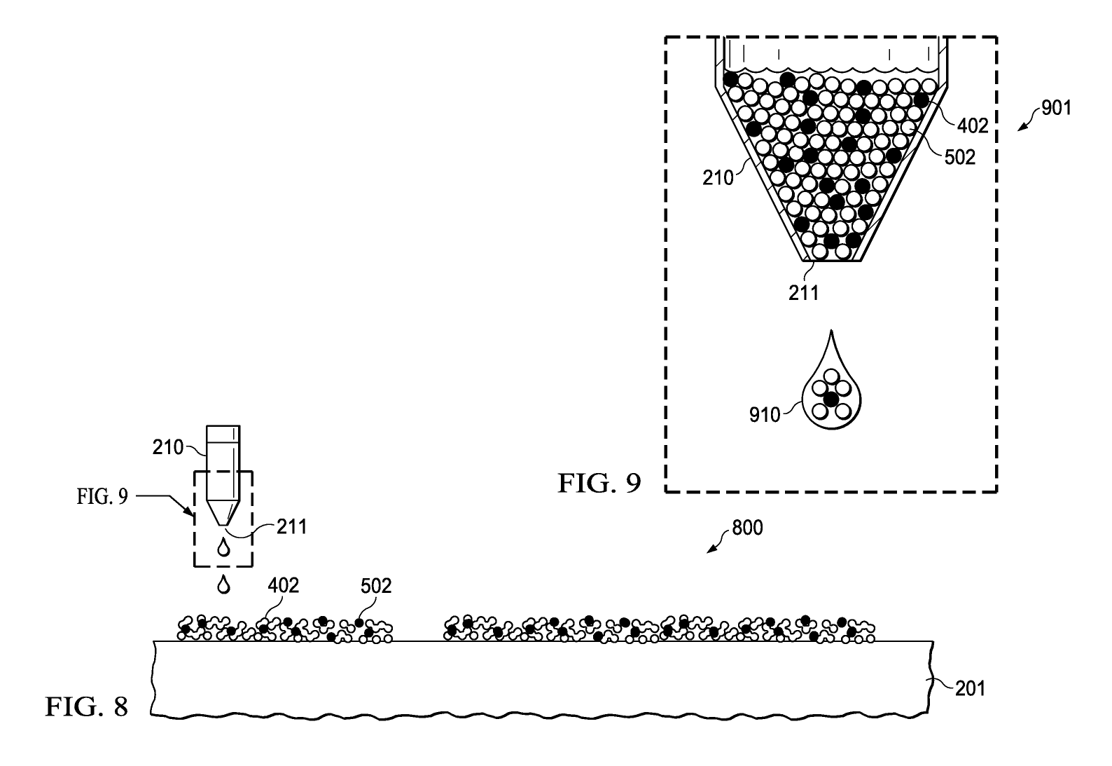

Another embodiment of the invention is a nanoparticle layer as depicted in FIG. 8, which mixes the nanoparticles 402 of the second material and the nanoparticles 502 of the third material into a single homogeneous layer 800. Joint layer 800 improves the adhesion between substrate 201 and package 701 by averaging the adhesion at the two interfaces substrate 201 to layer 800, and package 701 to layer 800.

The fabrication process for layer 800, as illustrated in FIGS. 8 and 9, is analogous to the fabrication processes described above for creating the nanoparticle layers 400 and 500. A computer-controlled inkjet printer is used with the solvent paste 901 comprising a mixture of nanoparticles 402 of the second material and nanoparticles 502 of the third material.

The method for adhesion improvement between two objects by a sintered semi-homogeneous nanoparticle layer of two nanoparticle materials begins by providing an object of a first material and an object of a fourth material. Then, a solvent paste is provided, which includes a semi-homogeneous mixture of nanoparticles of a second material and nanoparticles of a third material. The nanoparticles of the second material are able to form diffusion bonds to the first material by molecular diffusion into the surface-near region of the substrate made of the first material. The nanoparticles of the third material form adhesion bonds by intermolecular forces to the nanoparticles of the second material, and further form to the object of the fourth material chemical bonds due to electrical forces and/or mechanical bonds due to filling of pores/voids.

Using a computerized inkjet printing technique for the next process, a layer of the semi-homogeneous mixture of the solvent paste is additively deposited on the surface of the object of the first material. Energy is then applied to elevate the temperature for sintering together the nanoparticles of the second and the third materials, forming a sintered nanoparticle layer, and for concurrently diffusing second material into the region adjoining the surface of the object of the first material.

Next, the object of the fourth material is brought into contact with the sintered nanoparticle layer so that the chemical and/or mechanical bonding is actualized; the object of the fourth material is bonded to the nanoparticles of the third material.

FIG. 10 illustrates an exemplary embodiment of the enhanced adhesion by a bi-layer nanoparticle adhesion film in an exemplary semiconductor device, which includes a metallic leadframe and a plastic package. The exemplary embodiment is a semiconductor device 1000 with a leadframe including a pad 1001 for assembling a semiconductor chip 1010, tie bars 1002 connecting pad 1001 to the sidewall of the package, and a plurality of leads 1003. It should be noted that herein the tie bars may be referred to as straps. The chip terminals are connected to the leads 1003 by bonding wires 1030, which commonly include ball bond 1031 and stitch bond 1032. In the example of FIG. 10, leads 1003 are shaped as cantilevered leads; in other embodiments, the leads may have the shape of flat leads as used in Quad Flat No-Lead (QFN) devices or in Small Outline No-Lead (SON) devices. Along their longitudinal extension, straps 1002 of the exemplary device in FIG. 10 include bendings and steps, since pad 1001 and leads 1003 are not in the same plane. In other devices, straps 1002 are flat and planar, because pad 1001 and leads 1003 are in the same plane.

In FIG. 10, portions of the leadframe are marked by dashing 1020, which include in a bi-layer film made of nanoparticles. The film may include voids of random distribution and random three-dimensional configurations. Since the exemplary device 1000 includes a package 1070 for encapsulating chip 1010 and wire bonds 1030, any voids of the bi-layer film are filled by the polymeric compound. Package 1070 is made of a polymeric compound such as an epoxy-based thermoset polymer, formed in a molding process, and hardened by a polymerization process. The adhesion between the polymeric compound of package 1070 and the leadframe is improved by the bi-layer nanoparticle film. Other devices may have more and larger areas of the leadframe covered by the porous bi-layer nanoparticle film.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example in semiconductor technology, the invention applies not only to active semiconductor devices with low and high pin counts, such as transistors and integrated circuits, but also to combinations of active and passive components on a leadframe pad.

As another example, the invention applies not only to silicon-based semiconductor devices, but also to devices using gallium arsenide, gallium nitride, silicon germanium, and any other semiconductor material employed in industry. The invention applies to leadframes with cantilevered leads and to QFN and SON type leadframes.

As another example, the invention applies, in addition to leadframes, to laminated substrates and any other substrate or support structure, which is to be bonded to a non-metallic body.

It is therefore intended that the appended claims encompass any such modifications or embodiments.

We claim:

1. A device comprising:
a substrate of a first material, the substrate having a surface;
a nanoparticle layer of a second material on top of and in contact with the surface of the substrate, a substrate region adjoining the substrate surface comprising an admixture of the second material in the first material;
a nanoparticle layer of a third material on top of and in contact with the nanoparticle layer of the second material, the nanoparticles of the third material adhering to the nanoparticles of the second material; and
a package of a fourth material, the fourth material contacted to, and bonded to, the nanoparticle layer of the third material, the fourth material filling any voids in the layer of third material.

2. The device of claim 1 wherein the substrate of the first material is a laminated substrate including metallic regions.

3. The device of claim 1 wherein the substrate of the first material is one or more surfaces on a metallic leadframe.

4. The device of claim 3 wherein the first material of the metallic leadframe is selected from a group including copper, copper alloys, aluminum, aluminum alloys, iron-nickel alloys, and Kovar™.

5. The device of claim 4 wherein the metallic leadframe further includes plated layers selected from a group including nickel, palladium, gold, and tin.

6. The device of claim 1 wherein the fourth material includes a polymeric compound such as an epoxy-based molding compound.

7. The device of claim 1 wherein the second material is selected from a group including metals, metal oxides, oxides, and ceramics.

8. The device of claim 1 wherein the third material is selected from a group including polymers, oxides, ceramics, metals, and metal oxides.

9. The device of claim 1 wherein the adhering of the nanoparticles of the third material to the nanoparticles of the second material is based on intermolecular forces between the nanoparticles.

10. The device of claim 1 wherein the bonding of the fourth material to the nanoparticle layer of the third material is based on intermingling of the fourth material with the third material.

11. The device of claim 1 wherein the bonding of the fourth material to the nanoparticle layer of the third material is based on chemical bonding.

12. A method for substrate modification comprising:
providing a substrate of a first material, the substrate having a first surface;
additively depositing onto the first substrate a layer of a solvent paste including nanoparticles of a second material;
applying energy to the first solvent paste to increase the temperature to sinter together the nanoparticles of the second material and concurrently for diffusing the second material into a substrate region adjoining the first surface;
additively depositing onto the sintered nanoparticles of the second material a layer of a second solvent paste, the second solvent paste including nanoparticles of a third material; and
applying energy to the second solvent paste to increase the temperature to solidify the nanoparticles of the third material, the solidified nanoparticles of the third material adhering to the sintered nanoparticles of the second material, thereby forming a bi-layer nanoparticle film.

13. The method of claim 12 wherein the substrate is selected from a group including metallic substrates, metallic leadframes used for semiconductor devices, and laminated substrates including metallic layers alternating with insulating layers.

14. The method of claim 12 wherein the first material is selected from a group including copper, copper alloys, aluminum, aluminum alloys, iron-nickel alloys, and Kovar™.

15. The method of claim 14 wherein the first material includes a plated layer of a metal selected from a group including tin, silver, nickel, palladium, and gold.

16. The method of claim 12 wherein the method of additively depositing is selected from a group including screen printing, flexographic printing, gravure printing, dip coating, spray coating, and inkjet printing comprising piezoelectric, thermal, acoustic, and electrostatic inkjet printing.

17. The method of claim 12 wherein the second material is selected from a group including metals, metal oxides, oxides, and ceramics.

18. The method of claim 12 wherein the third material is selected from a group including polymers, oxides, ceramics, metals, and metal oxides.

19. The method of claim 12 wherein the energy for sintering the second nanoparticles is selected from a group including thermal energy, photonic energy, electromagnetic energy, and chemical energy.

20. A method for substrate modification comprising:
providing a first material;
additively depositing on a surface of the first material a layer of a solvent paste comprising a semi-homogeneous mixture of:
nanoparticles of a second material bondable to the first material by interdiffusion; and
nanoparticles of a third material adhering to the second material and bondable to a fourth material chemically and mechanically;
applying energy to increase the temperature for sintering together the nanoparticles of the second and the third materials, forming a sintered nanoparticle layer, and concurrently for diffusing second material into a region adjoining the surface of the first material; and
bringing the fourth material in contact with the sintered nanoparticle layer, thereby bonding the fourth material to the nanoparticles of the third material.

21. A method for enhancing adhesion of packaged semiconductor devices, comprising:
providing a substrate of a first material, the substrate having a first surface;
additively depositing onto the first surface a layer of a first solvent paste, the first solvent paste including nanoparticles of a second material;
applying energy to the first solvent paste to increase the temperature of the first solvent paste to sinter together the nanoparticles of the second material and concurrently for diffusing the second material into a substrate region adjoining the first surface;
additively depositing onto the sintered nanoparticles of the second material a layer of a second solvent paste, the second solvent paste including nanoparticles of a third material;
applying energy to the second solvent paste to increase the temperature of the second solvent paste to solidify the nanoparticles of the third material, the solidified nanoparticles of the third material adhering to the sintered nanoparticles of the second material, thereby forming a bi-layer nanoparticle film; and
encapsulating the bi-layer nanoparticle film and at least portions of the substrate in a fourth material, the fourth material chemically bondable to the solidified nanoparticles of the third material.

22. The method of claim 21 wherein the substrate is a metallic leadframe for use in semiconductor devices with the first material selected from a group including copper, copper alloys, aluminum, aluminum alloys, iron-nickel alloys, and Kovar™.

23. The method of claim 22 wherein the first material includes a plated layer of a metal selected from a group including tin, silver, nickel, palladium, and gold.

24. The method of claim 21 wherein the second material is selected from a group including metals, metal oxides, oxides, and ceramics.

25. The method of claim 21 wherein the third material is selected from a group including polymers, oxides, ceramics, metals, and metal oxides.

26. The method of claim 21 further including, before the process of encapsulating, the process of assembling a semiconductor chip on the substrate so that the chip will be positioned inside the package after the process of encapsulating.
